(19) United States
(12) Patent Application Publication
(10) Pub. No.: US 2026/0342283 A1
(43) Pub. Date: Oct. 29, 2026

(54) CRYSTAL OSCILLATOR DRIVER CIRCUIT HAVING ADAPTIVE CURRENT REGULATION FUNCTION

(71) Applicant: SigmaStar Technology Ltd., Xiamen (CN)

(72) Inventors: Hong Kai LIN, Xiamen (CN); Chen Hui LUO, Xiamen (CN); Jian Feng XUE, Xiamen (CN); Zhun CHEN, Xiamen (CN)

(21) Appl. No.: 19/412,999

(22) Filed: Dec. 9, 2025

(30) Foreign Application Priority Data
Apr. 29, 2025 (CN) 202510551648.6

(51) Int. Cl. H03B 5/04; H03B 5/36

(52) U.S. Cl. CPC H03B 5/04; H03B 5/364

(57) ABSTRACT

A crystal oscillator driver circuit includes an amplifier, a current generating circuit, a reference voltage generating circuit, a driver circuit and a detection circuit. The amplifier generates a control voltage according to a reference voltage and a detection voltage. The current generating circuit generates a first current and a second current according to the control voltage. The reference voltage generating circuit receives the first current and generates the reference voltage. The driver circuit receives the second current and drives a crystal according to the second current. The detection circuit generates the detection voltage according to a first voltage associated with the crystal. A ratio of the first current to the second current is less than 1.

This application claims the benefit of China application Serial No. CN202510551648.6, filed on Apr. 29, 2025, the subject matter of which is incorporated herein by reference.

### BACKGROUND OF THE INVENTION

### Field of the Invention

The present application relates to a crystal oscillator driver circuit, and more particularly to a crystal oscillator driver circuit with an adaptive current regulation function.

### Description of the Related Art

Transistor oscillators are often applied in related applications of clock generation to provide a stable reference frequency or reference clock signal. In a current crystal oscillator driver circuit, a plurality of low-pass filters are usually used to obtain a reference voltage according to a voltage of an end point of a crystal, and drive the crystal according to the reference voltage. However, as the number of low-pass filters used increases, the crystal oscillator driver circuit requires a larger circuit area, leading to increases in both overall costs and power consumption.

### SUMMARY OF THE INVENTION

In some embodiments, it is an object of the present application to provide a crystal oscillator driver circuit with an adaptive current regulation function so as to improve the issues of the prior art.

In some embodiments, a crystal oscillator driver circuit includes an amplifier, a current generating circuit, a reference voltage generating circuit, a driver circuit and a detection circuit. The amplifier generates a control voltage according to a reference voltage and a detection voltage. The current generating circuit generates a first current and a second current according to the control voltage. The reference voltage generating circuit receives the first current and generates the reference voltage. The driver circuit receives the second current and drives a crystal according to the second current. The detection circuit generates the detection voltage according to a first voltage associated with the crystal. A ratio of the first current to the second current is less than 1.

Features, implementations and effects of the present application are described in detail in preferred embodiments with the accompanying drawings below.

### BRIEF DESCRIPTION OF THE DRAWINGS

To better describe the technical solution of the embodiments of the present application, drawings involved in the description of the embodiments are introduced below. It is apparent that, the drawings in the description below represent merely some embodiments of the present application, and other drawings apart from these drawings may also be obtained by a person skilled in the art without involving inventive skills.

FIG. 1 is a schematic diagram of a crystal oscillator driver circuit according to some embodiments of the present application.

FIG. 2 is a circuit schematic diagram of the crystal oscillator driver circuit in FIG. 1 according to some embodiments of the present application.

FIG. 3 is a schematic diagram of waveforms of the control voltage, the reference voltage, the detection voltage and the voltage associated with a crystal in FIG. 2 according to some embodiments of the present application.

### DETAILED DESCRIPTION OF THE INVENTION

All terms used in the literature have commonly recognized meanings. Definitions of the terms in commonly used dictionaries and examples discussed in the disclosure of the present application are merely exemplary, and are not to be construed as limitations to the scope or the meanings of the present application. Similarly, the present application is not limited to the embodiments enumerated in the description of the application.

The term “coupled” or “connected” used in the literature refers to two or multiple elements being directly and physically or electrically in contact with each other, or indirectly and physically or electrically in contact with each other, and may also refer to two or more elements operating or acting with each other. As given in the literature, the term “circuit” may be a device connected by at least one transistor and/or at least one active element by a predetermined means so as to process signals.

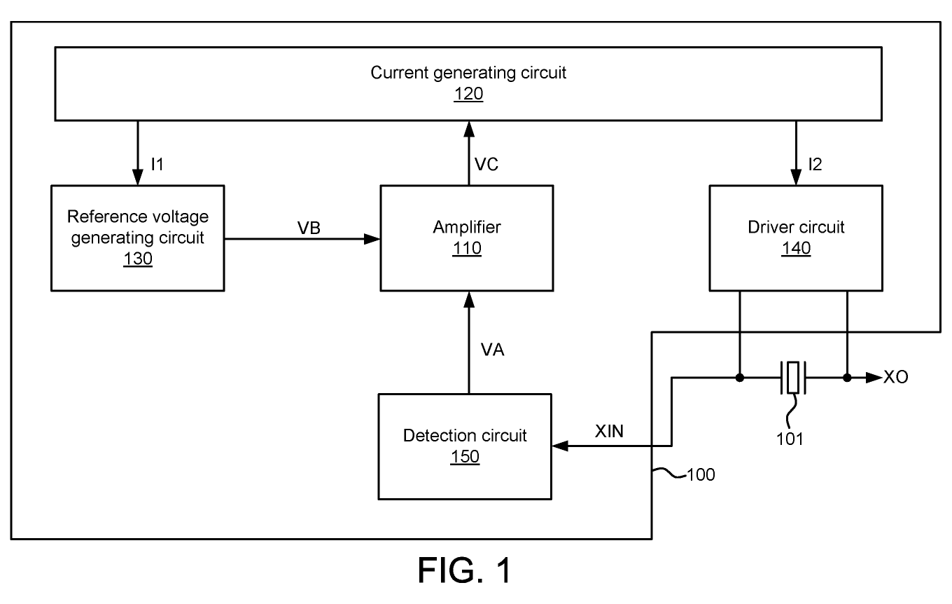

FIG. 1 shows a schematic diagram of a crystal oscillator driver circuit 100 according to some embodiments of the present application. In some embodiments, the crystal oscillator driver circuit 100 may be applied in real-time clock (RTC) applications to provide highly accurate clock signals. In some embodiments, RTC applications usually require related circuits to continue working for an extended period of time in a battery-powered environment. Thus, the crystal oscillator driver circuit 100 needs to provide a relatively low power consumption and be able to work in a relatively low-voltage environment, so as to meet related requirements of the RTC applications above.

The crystal oscillator driver circuit 100 includes an amplifier 110, a current generating circuit 120, a reference voltage generating circuit 130, a driver circuit 140 and a detection circuit 150. The amplifier 110 generates a control voltage VC according to a reference voltage VB and a detection voltage VA. The current generating circuit 120 generates a current I1 and a current I2 according to the control voltage VC, wherein a ratio of the current I1 to the current I2 is set to be less than 1. The reference voltage generating circuit 130 receives the current I1 and accordingly generates the reference voltage VB. The driver circuit 140 receives the current I2 and drives a crystal 101 according to the current I2. The detection circuit 150 generates the detection voltage VA according to a voltage associated with the crystal 101 (for example but not limited to, a voltage XIN on an end point of the crystal 101). In some embodiments, the crystal 101 may be, for example but not limited to, a quartz crystal. The driver circuit 140 may provide the crystal 101 with a negative impedance, such that the crystal 101 can enter an oscillation state according to the current I2 to thereby generate a reference signal XO. In some embodiments, the reference signal XO may be provided to a comparator (not shown), for the comparator to generate a stable clock signal based on the reference signal XO.

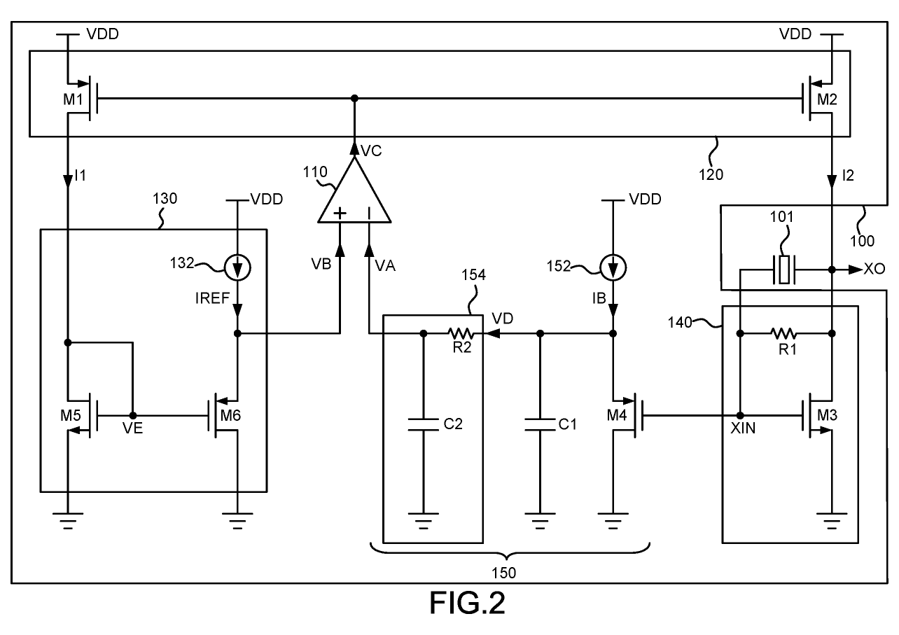

FIG. 2 shows a circuit schematic diagram of the crystal oscillator driver circuit 100 in FIG. 1 according to some embodiments of the present application. A negative input terminal of the amplifier 110 receives the detection voltage VA, and a positive input terminal of the amplifier 110 receives the reference voltage VB. The current generating circuit 120 includes a transistor M1 and a transistor M2. A first terminal (for example, the source) of the transistor M1 and a first terminal of the transistor M2 receive a power supply voltage VDD. A control terminal (for example, the gate) of the transistor M1 and a control terminal of the transistor M2 are coupled to an output terminal of the amplifier 110 to receive the control voltage VC. A second terminal (for example, the drain) of the transistor M1 generates the current I1, and transmits the current I1 to the reference voltage generating circuit 130. A second terminal of the transistor M2 generates the current I2, and transmits the current I2 to the driver circuit 140. In other words, with the configuration above, the transistor M1 is able to generate the current I1 according to the control voltage VC, and the transistor M2 is able to generate the current I2 according to the control voltage VC. In this embodiment, the current generating circuit 120 is implemented by a current mirror circuit. As described above, the ratio between the current I1 to the current I2 is less than 1, that is, the current I2 is greater than the current I1. Correspondingly, an aspect ratio of the transistor M1 may be configured to be less than an aspect ratio of the transistor M2, so as to set the ratio relationship of the current I1 and the current I2.

The driver circuit 140 may include a resistor R1 and a transistor M3. A first terminal (for example, the drain) of the transistor M3 is coupled to the transistor M2 to receive the current I2, a second terminal (for example, the source) of the transistor M3 is coupled to ground, and a control terminal (for example, the gate) of the transistor M3 is coupled to the detection circuit 150. The resistor R1 and the crystal 101 are coupled in parallel between the control terminal of the transistor M3 and the first terminal of the transistor M3, wherein a first terminal of the crystal 101 provides the voltage XIN and a second terminal of the crystal 101 generates the reference signal XO. In one embodiment, the driver circuit 140 may further include a load capacitor (not shown), which may be coupled to the second terminal of the crystal 101. With the configuration above, the driver circuit 140 is able to provide a negative impedance to the crystal 101 to assist the crystal 101 to enter an oscillation state. The transistor M3 is driven by the current I2, and thus the transconductance of the transistor M3 is determined by a current. The transconductance of the transistor M3 determines the size of the negative impedance above. In some embodiments, when the crystal 101 has not yet entered an oscillation state (that is, it has not yet started oscillating), the reference voltage VB is lower than the detection voltage VA such that the amplifier 110 generates the control voltage VC in a lower value. In this case, the transistor M2 generates the current I2 in a higher value in a way that the transconductance of the transistor M3 increases, so as to generate a larger negative impedance for the crystal 101 to more easily enter an oscillation state (that is, reducing the time needed for the crystal 101 to start oscillating).

In some embodiments, the detection circuit 150 includes a capacitor C1, and may charge or discharge the capacitor C1 according to the voltage XIN associated with the crystal 101 to generate the detection voltage VA. For example, the capacitor C1 is charged or discharged to generate a voltage VD. In some embodiments, the detection circuit 150 further includes a low-pass filter (LPF) 154. The low-pass filter 154 generates the detection voltage VA according to the voltage VD. More specifically, the detection circuit 150 includes a current source 152, a capacitor C1, a transistor M4 and the low-pass filter 154. The current source 152 receives the power supply voltage VDD and provides a bias current IB to charge the capacitor C1. A first terminal of the transistor M4 is coupled to the current source 152, a second terminal of the transistor M4 is coupled to ground, and a control terminal of the transistor M4 is coupled to the capacitor C1, the crystal 101 and the driver circuit 140 to receive the voltage XIN. A first terminal of the capacitor C1 is coupled to the current source 152, the first terminal of the transistor M4 and an input terminal of the low-pass filter 154, and a second terminal of the capacitor C1 is coupled to ground. The transistor M4 is selectively turned on according to the voltage XIN to discharge the capacitor C1.

When the crystal 101 has not yet started oscillating, the bias current IB is greater than a current flowing through the transistor M4, such that charging of the capacitor C1 begins to generate the voltage VD in a higher value. In this case, the low-pass filter 154 may generate the detection voltage VA in a higher value according to the voltage VD for the transistor M2 to generate the current I2 also in a higher value. Once the crystal 101 has entered an oscillation state, the amplitude of the voltage XIN increases such that the current of the transistor M4 becomes higher than the bias current IB, and discharging of the capacitor C1 begins to generate the voltage VD in a lower value. In this case, the low-pass filter 154 may generate the detection voltage VA in a lower value according to the voltage VD such that the amplifier 110 generates the control voltage VC in a higher value, and thus the transistor M2 may generate the current I2 in a lower value to effectively reduce the overall power consumption after the crystal 101 has entered an oscillation state. In other words, the operations above form an adaptive current regulation function. That is, when the crystal 101 has not yet started oscillating, the current generating circuit 120 generates the current I2 in a higher value to reduce the time that the crystal 101 needs to start oscillating. Once the crystal 101 has entered an oscillation state, the current generating circuit 120 may accordingly generate the current I2 in a lower value to thereby reduce the overall power consumption.

In some embodiments, the low-pass filter 154 may include a resistor R2 and a capacitor C2. A first terminal of the resistor R2 is coupled to the capacitor C1 to receive the voltage VD, a second terminal of the resistor R2 is coupled to a first terminal of the capacitor C2, a second terminal of the capacitor C2 is coupled to ground, and a second terminal of the resistor R2 generates the detection voltage VA and transmits the detection voltage VA to the negative input terminal of the amplifier 110. It should be noted that the implementation details of the low-pass filter 154 above are examples, and are not to be construed as limitation to the present application. Various related configurations capable of implementing low-pass filtering are encompassed with the scope of protection of the present application.

The reference voltage generating circuit 130 includes a current source 132, a transistor M5 and a transistor M6. The current source 132 receives the power supply voltage VDD and generates a reference current IREF. A first terminal of the transistor M5 is coupled to a second terminal of the transistor M1 to receive a current, the first terminal of the transistor M5 is further coupled to a control terminal of the transistor M5 and generates a bias voltage VE, and a second terminal of the transistor M5 is coupled to ground. A first terminal of the transistor M6 is coupled to the current source 132 to receive the reference current IREF and generates the reference voltage VB, a second terminal of the transistor M6 is coupled to ground, and a control terminal of the transistor M6 is coupled to a control terminal of the transistor M5 to receive the bias voltage VE. With the configuration above, the transistor M5 is configured as a diode-connected transistor to generate the corresponding bias voltage VE based on the current I1. The transistor M6 may generate the corresponding reference voltage VB according to the bias voltage VE and the reference current IREF.

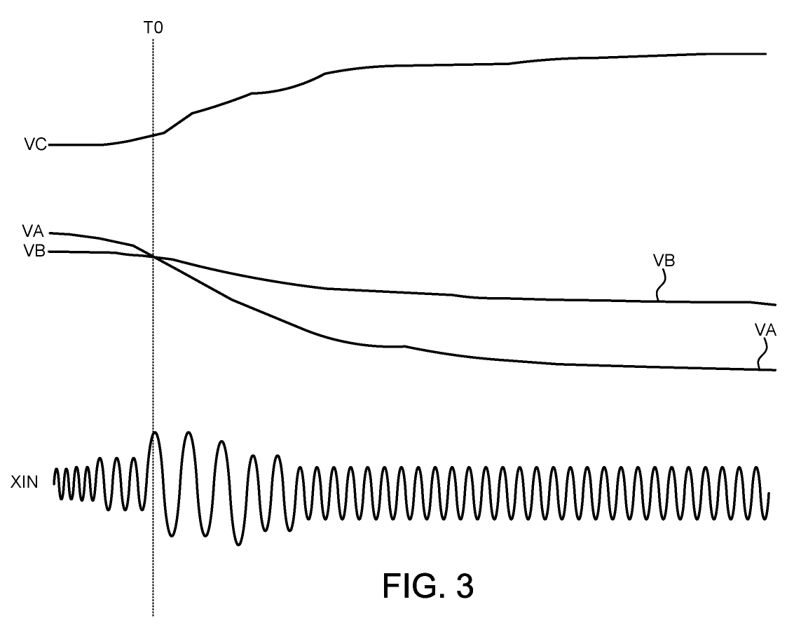

FIG. 3 shows a schematic diagram of waveforms of the control voltage VC, the reference voltage VB, the detection voltage VA and the voltage XIN associated with the crystal 101 in FIG. 2 according to some embodiments of the present application. Before a timing T0, the crystal 101 has not yet entered an oscillation state (that is, stable oscillation has not yet started). As described above, the current generating circuit 120 is implemented by a current mirror circuit, and by configuring the ratio between the current I1 to the current I2, the reference voltage VB may be lower than the detection voltage VA (when the crystal 101 has not yet entered an oscillation state). Thus, the amplifier 110 generates the control voltage VC in a lower value. In response to the control voltage VC in a lower value, the current I2 increases to enable the driver circuit 140 to speed up the time for the crystal 101 to enter an oscillation state. After the timing T0, the crystal 101 enters an oscillation state, and the amplitude of voltage XIN on one terminal of the crystal 101 accordingly increases. Thus, the capacitor C1 is discharged, and the detection circuit 150 generates the detection voltage VA in a lower value. Meanwhile, the reference voltage generating circuit 130 generates the reference voltage VB in a higher value. In other words, once the crystal 101 has entered an oscillation state, the reference voltage VB is higher than the detection voltage VA. In this case, the amplifier 110 generates the control voltage VC in a higher value to thereby reduce the current I1 and the current I2, so as to reduce the overall power consumption.

It should be noted that, the waveforms of the signals in FIG. 3 are merely for explaining relationship in changes of timings and voltage levels during related operations and are not to be construed as limitations to the present application, wherein the actual frequency or the actual amplitude of the voltage XIN is not limited to the exemplary waveform shown in FIG. 3.

In conclusion, the crystal oscillator driver circuit provided according to some embodiments of the present application has an adaptive current regulation function, and is able to self-regulate overall currents according to an oscillation state of a crystal, that is, a current is increased before the oscillator starts oscillating to reduce the time needed to start oscillating, and the current is automatically reduced to reduce the power consumption once the crystal has reached stable oscillation. Moreover, the crystal oscillator driver circuit provided according to some embodiments of the present application is able to generate a reference voltage with techniques of circuits such as the use of a current mirror circuit, and does not involve a plurality of low-pass filters, hence reducing the overall circuit area.

While the present application has been described by way of example and in terms of the preferred embodiments, it is to be understood that the disclosure is not limited thereto. Various modifications may be made to the technical features of the present application by a person skilled in the art on the basis of the explicit or implicit disclosures of the present application. The scope of the appended claims of the present application therefore should be accorded with the broadest interpretation so as to encompass all such modifications.

What is claimed is:

1. A crystal oscillator driver circuit, comprising:
an amplifier, generating a control voltage according to a reference voltage and a detection voltage;
a current generating circuit, generating a first current and a second current according to the control voltage;
a reference voltage generating circuit, receiving the first current and generating the reference voltage;
a driver circuit, receiving the second current and driving a crystal according to the second current; and
a detection circuit, generating the detection voltage according to a first voltage associated with the crystal,
wherein a ratio between the first current to the second current is less than 1.

2. The crystal oscillator driver circuit according to claim 1, wherein when the crystal has not yet entered an oscillation state, the reference voltage is lower than the detection voltage.

3. The crystal oscillator driver circuit according to claim 1, wherein when the crystal has entered an oscillation state, the detection voltage is lower than the reference voltage.

4. The crystal oscillator driver circuit according to claim 1, wherein when the crystal has entered an oscillation state, the second current decreases.

5. The crystal oscillator driver circuit according to claim 1, wherein the detection circuit comprises a capacitor, and the detection circuit charges or discharges the capacitor according to the first voltage to generate the detection voltage.

6. The crystal oscillator driver circuit according to claim 5, wherein the capacitor is charged or discharged to generate a second voltage, the detection circuit further comprises a low-pass filter, and the low-pass filter generates the detection voltage according to the second voltage.

7. The crystal oscillator driver circuit according to claim 5, wherein the detection circuit further comprises:
a current source, generating a bias current to charge the capacitor; and
a transistor, coupled to the current source and the capacitor, and selectively turned on according to the first voltage to discharge the capacitor.

8. The crystal oscillator driver circuit according to claim 1, wherein the current generating circuit comprises:
a first transistor, generating the first current according to the control voltage; and
a second transistor, generating the second current according to the control voltage.

9. The crystal oscillator driver circuit according to claim 1, wherein the reference voltage generating circuit comprises:
a current source, generating a reference current;
a first transistor, receiving the first current, configured as a diode-connected transistor to generate a bias voltage; and
a second transistor, generating the reference voltage according to the bias voltage and the reference current.

10. The crystal oscillator driver circuit according to claim 1, wherein the driver circuit comprises:
a transistor, wherein a first terminal of the transistor receives the second current, a second terminal of the transistor is coupled to ground, and the crystal is coupled between the first terminal of the transistor and a control terminal of the transistor; and
a resistor, coupled between the first terminal of the transistor and the control terminal of the transistor.

11. The crystal oscillator driver circuit according to claim 1, wherein the current generating circuit is implemented by a current mirror circuit.
